(19) United States
(12) Patent Application Publication
(10) Pub. No.: US 2002/0196828 A1
(43) Pub. Date: Dec. 26, 2002

(54) Semiconductor laser device

(75) Inventors: Shinji Abe, Tokyo (JP); Tetsuya Yagi, Tokyo (JP); Motoharu Miyashita, Tokyo (JP); Harumi Nishiguchi, Tokyo (JP); Yuji Ohkura, Tokyo (JP); Nobuyuki Kasai, Tokyo (JP); Yoshihisa Tashiro, Tokyo (JP); Junji Tanimura, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/136,473

(22) Filed: May 2, 2002

(30) Foreign Application Priority Data
Jun. 14, 2001 (JP) 2001-179755

(51) Int. Cl. H01S 5/16

(52) U.S. Cl. 372/46

(57) ABSTRACT

In a semiconductor laser device including a window structure region formed by disordering an active layer or active layers of a quantum well structure by silicon ion implantation and a subsequent heat treatment, a dislocation loop is substantially absent in the window structure region and the vicinity thereof (upper clad layer). Accordingly, deterioration of the semiconductor laser device induced by dislocation loops can be prevented, and reliability of the semiconductor laser device can be improved.

### BACKGROUND OF THE INVENTION

1.Field of the Invention

The present invention relates to a semiconductor laser device including a window structure region formed by a disordering process of a quantum well structure.

2.Description of the Related Art

Attendant on an increase in the speed of recordable or rewritable-type high density optical devices such as CD-R/RW, semiconductor laser devices used as light sources are strongly demanded to have a higher output. As one of the techniques to enhance the output of the semiconductor laser device, a window structure semiconductor laser device including a window structure region having a bandgap greater than the bandgap of the semiconductor of an active layer on a facet or facets of the semiconductor laser device has drawn attention in view of its effect of suppressing catastrophic optical damage (COD) destruction which inhibits the increase of output.

For example, S. A. Schwarz et al have reported in Applied Physics Letters, 1987, Vol. 50, No. 5, pp. 281-283 that a superlattice consisting of AlAs/GaAs can be disordered by Si ion implantation and a subsequent heat treatment. By applying the disordering of crystals using the Si ion implantation to a facet or facets of a semiconductor laser device having an active layer constituted of a quantum well or quantum wells, it is possible to disorder the active layer and to fabricate a window structure region having a bandgap greater than the bandgap of the semiconductor of the active layer.

FIG. 6 shows the structure of a facet of a conventional window structure AlGaAs semiconductor laser device fabricated by doping Zn in an upper clad layer 9 and using Si ion implantation and heat treatment. In FIG. 6, reference numeral 1 denotes a surface electrode, 2 denotes a p-GaAs contact layer, 3 denotes a p-Al_{0.49}Ga_{0.51}As upper clad layer, 4 denotes an n-Al_{0.65}Ga_{0.35}As block layer, 5 denotes an Al_{0.33}Ga_{0.67}As/Al_{0.12}Ga_{0.88}As double quantum well (DQW) (well layer=Al_{0.10}Ga_{0.90}As, 8.4 nm; barrier layer=Al_{0.35}Ga_{0.65}As, 8.4 nm) active layer, 6 denotes an n-Al_{0.48}Ga_{0.52}As lower clad layer, 7 denotes an n-GaAs substrate, 8 denotes a back side electrode, 9 denotes a p-Al_{0.48}Ga_{0.52}As upper clad layer (Zn doped), and 10 denotes a window structure region.

Here, the window structure region 10 is fabricated by Si ion implantation at an acceleration voltage of 95 keV and a dose of 1.68×10¹⁴ atoms/cm² and a subsequent heat treatment at 800° C. for 30 minutes. Under these conditions, the peak concentration of Si is about 1.4×10¹⁹ atoms/cm³. The photoluminescence wavelength (hereinafter referred to simply as PL wavelength) of a window portion at room temperature is 720 nm, which is shorter than that (775 nm) of non-window portions (bandgap is greater), thus producing a window effect. With the window structure region 10 provided at the facet, COD is suppressed, and a higher output is realized.

FIG. 7 shows a transmission electron microscope (TEM) photograph of a window structure region in the above-mentioned conventional window structure AlGaAs semiconductor laser device. In this evaluation, the resolution of TEM was 1.7 angstrom. It is seen that dislocation loops 11 are recognized at an upper portion of the active layer (in the upper clad layer 9).

As to the cause of the dislocation loops observed in the AlGaAs layer implanted with Si ion, there has been no report yet. However, K. S. Jones et al have reported in the Journal of Applied Physics, 1991, Vol. 70, No. 11, pp. 6790-6795, that the dislocation loops observed in a GaAs layer implanted with Si ions at an acceleration voltage of 185 keV and a dose of 1×10¹⁵ atoms/cm² are the so-called “type-V defects” related to aggregates.

In addition, S. Muto et al have reported in Philosophical Magazine A, 1992, Vol. 66, No. 2, pp. 257-268, that the dislocation loops observed in a GaAs crystal grown by an inclined cooling method heavily doped with 2×10¹⁹ to 4×10¹⁹ atoms/cm³ of Si arise from Si aggregated on (111) planes.

With these reports, it is assumed that the dislocation loops 11 observed in FIG. 7 were generated as a result of the aggregates of Si, introduced in the crystal in excess of the solid solubility limit in the matrix material, onto (111) planes during the heat treatment process.

Meanwhile, for disordering, it is necessary to diffuse Si atoms by heat treatment after ion implantation. For diffusion of Si atoms, it is essential that Si concentration gradient should be present in the vicinity of the active layer 5, so that the Si ion implantation profile must be so selected as to have a peak of concentration on the upper side (p-Al_{0.48}Ga_{0.52}As upper clad layer 9) of the active layer 5. In such a Si profile, the Si concentration at the peak is at least higher than the concentration in the active layer 5. Besides, as the Si concentration in the active layer 5 is set higher, the disordering of the window structure region 10 becomes easier.

S. A. Schwarz et al, in the above-mentioned report, have carried out Si ion implantation under the conditions of an acceleration voltage of 180 keV and a dose of 3×10¹⁵ atoms/cm². Under the conditions, the peak concentration of Si is as high as about 8×10¹⁹ atoms/cm³. Besides, T. Venkatesan et al, in Applied Physics Letters, 1986, Vol. 49, No. 12, pp. 701-703, have reported experimental examples under the conditions of an acceleration voltage of 180 keV and doses of 3×10¹³, 1×10¹⁵ and 3×10¹⁵ atoms/cm². From the diagram of diffusion coefficient of Al being the matrix material described in the report, it is estimated that disordering did not occur at least under the condition of a dose of 3×10¹³ atoms/cm².

From the experiments carried out by the present inventors, it has been found that for disordering of an active layer 5 (DQW: well layer=Al_{0.10}Ga_{0.90}As, 8.4 nm; barrier layer=Al_{0.35}Ga_{0.65}As, 8.4 nm) of an AlGaAs semiconductor laser device having the structure shown in FIG. 6, the Si concentration in the active layer 5 must be not less than 1.0×10¹⁸ atoms/cm³.

However, an unprepared increase of the Si dose at the time of ion implantation in order for easier promotion of disordering results in that the Si concentration exceeds the solid solubility limit in AlGaAs and dislocation loops would be formed in the semiconductor layer upon heat treatment.

FIG. 8 shows the results of reliability tests for the above-mentioned semiconductor laser devices. In the figure, the axis of ordinate is the operating current, the axis of abscissa is the operating time, and it is shown that the semiconductor laser device is deteriorated at the time when the operating current required for emission increases abruptly. As seen from the figure, most semiconductor laser devices are deteriorated within 300 hours.

In addition, as a result of the degradation analysis of such conventional semiconductor laser devices, it has been found that degradation starts from the dislocation loops 11 shown above. Therefore, in order to enhance the reliability of the semiconductor laser device, it is necessary to prohibit the generation of the dislocation loops 11 formed in the upper clad layer 9.

Meanwhile, as described above, in order to obtain a window structure by disordering of a quantum well structure, a heat treatment must be carried out after Si ion implantation. The quality of the window structure (the size of the bandgap of the semiconductor of the window structure region and the like) is determined by the heat treatment conditions. For example, in a heat treatment in an ordinary heat treatment furnace, the heat treatment conditions necessary for disordering of an AlGaAs quantum well structure are not less than 800° C. and 30 minutes.

FIG. 9 shows the relationship between various heat treatment conditions and the PL wavelength of the window portion at room temperature, for devices fabricated by Si ion implantation at an acceleration voltage of 95 keV and a dose of 1.68×10¹⁴ atoms/cm². Here, the PL wavelength is proportional to the reciprocal of the bandgap, and the function as the window structure in the semiconductor device is better as the PL wavelength is shorter. As seen from FIG. 9, higher heat treatment temperature or longer heat treatment time (hereinafter referred to simply as augmenting the heat treatment conditions) is needed for improvement of the window structure function.

However, in a conventional semiconductor laser device using zinc (Zn) as an acceptor, Zn with a high thermal diffusion coefficient diffuses into the active layer 5 or the n-type clad layer 6 during heat treatment, so that strengthening the heat treatment conditions leads to the problem that the carrier concentration in the p-type clad layer 9 is lowered and the density of free carriers in the active layer 5 is increased.

The results of analysis with secondary ion mass spectroscopy (SIMS) of a semiconductor laser device using Zn as an acceptor and subjected to a heat treatment at 820° C. for 60 minutes are shown in FIG. 10. From the figure it is seen that Zn doped in the upper clad layer 9 has diffused into not only the active layer 5 but also the n-type clad layer 6. Because the total amount of Zn is constant, the diffusion of Zn reduces the amount of Zn in the upper clad layer 9 in which it is to be intrinsically present, resulting in that the carrier concentration in the upper clad layer 9 is lowered below a set point.

In the semiconductor laser devices in such conditions, the effect of confining electrons in the active layer particularly at high temperatures is weakened, and temperature characteristics in operating current-light output characteristics are all poor as shown in FIG. 11. Besides, when an excess of Zn diffuses into the active layer 5 to increase the free carrier density in the active layer 5, degradation of laser characteristics such as emission efficiency would occur more easily.

### SUMMARY OF THE INVENTION

The present invention has been made for solving the above-mentioned problems. Accordingly, it is an object of the present invention to obtain a sufficiently high reliability, in a semiconductor laser device having a window structure using a disordering process of a quantum well structure.

It is another object of the present invention to obtain favorable temperature characteristics, in a semiconductor device having a window structure using a disordering process of a quantum well structure.

According to one aspect of the present invention, a semiconductor laser device comprises a window structure region formed by disordering an active layer or active layers of a quantum well structure by silicon ion implantation and a subsequent heat treatment, and a dislocation loop is substantially absent in and in the vicinity of said window structure region.

According to another aspect of the present invention, a semiconductor laser device comprises a window structure region formed by disordering an active layer or active layers of a quantum well structure by silicon ion implantation and a subsequent heat treatment, and the peak value of concentration of silicon in and in the vicinity of said window structure region is in the range of 1.0×10¹⁸ to 1.0×10¹⁹ atoms/cm³.

Other and further objects, features and advantages of the invention will appear more fully from the following description.

### BRIEF DESCRIPTION OF THE DRAWINGS

The present invention will be more apparent from the following detailed description, when taken in conjunction with the accompanying drawings, in which;

FIG. 1A shows an end view of a window structure AlGaAs semiconductor laser device with a Si peak density in the semiconductor of 8×10¹⁸ atoms/cm³;

FIG. 1B shows a central sectional view of a window structure AlGaAs semiconductor laser device with a Si peak density in the semiconductor of 8×10¹⁸ atoms/cm³;

FIG. 2 is a TEM photograph (resolution of 1.7 angstrom) of and of the vicinity of a window structure region in a window structure AlGaAs semiconductor laser device with a Si peak density in the semiconductor of 8×10¹⁸ atoms/cm³;

FIG. 3A shows an end view of a window structure semiconductor laser device having an upper clad layer characterized by use of carbon as a p-type dopant;

FIG. 3B shows a central sectional view of a window structure semiconductor laser device having an upper clad layer characterized by use of carbon as a p-type dopant;

FIG. 4 shows the result of SIMS analysis (after a heat treatment at 820° C. for 60 minutes) of the vicinity of the interface between an upper clad layer and an active layer using carbon as a p-type dopant;

FIG. 5 shows temperature characteristics of a window structure semiconductor laser device characterized by use of carbon as a p-type dopant;

FIG. 6 is an end view of a conventional window structure semiconductor laser device having a Zn-doped upper clad layer and a Si peak density in the semiconductor of 1.4×10¹⁹ atoms/cm³;

FIG. 7 is a TEM photograph (resolution of 1.7 angstrom) of and of the vicinity of a window structure region in a conventional window structure semiconductor laser device having a Zn-doped upper clad layer and a Si peak density in the semiconductor of 1.4×10¹⁹ atoms/cm³;

FIG. 8 is a diagram showing reliability of a conventional window structure semiconductor laser device having a Zn-doped upper clad layer and a Si peak density in the semiconductor of 1.4×10¹⁹ atoms/cm³;

FIG. 9 is a diagram showing the relationship between various heat treatment conditions and photoluminescence wavelength of a window structure region at room temperature;

FIG. 10 shows the results of SIMS analysis (after a heat treatment at 820° C. for 60 minutes) of a conventional window structure semiconductor laser device applying Zn as a p-type dopant; and

FIG. 11 shows temperature characteristics of a conventional window structure semiconductor laser device having a Zn-doped upper clad layer and a Si peak density in the semiconductor of 1.4×10¹⁹ atoms/cm³.

### DETAILED DESCRIPTION OF THE PREFERRED EMBODIMENT

First Embodiment

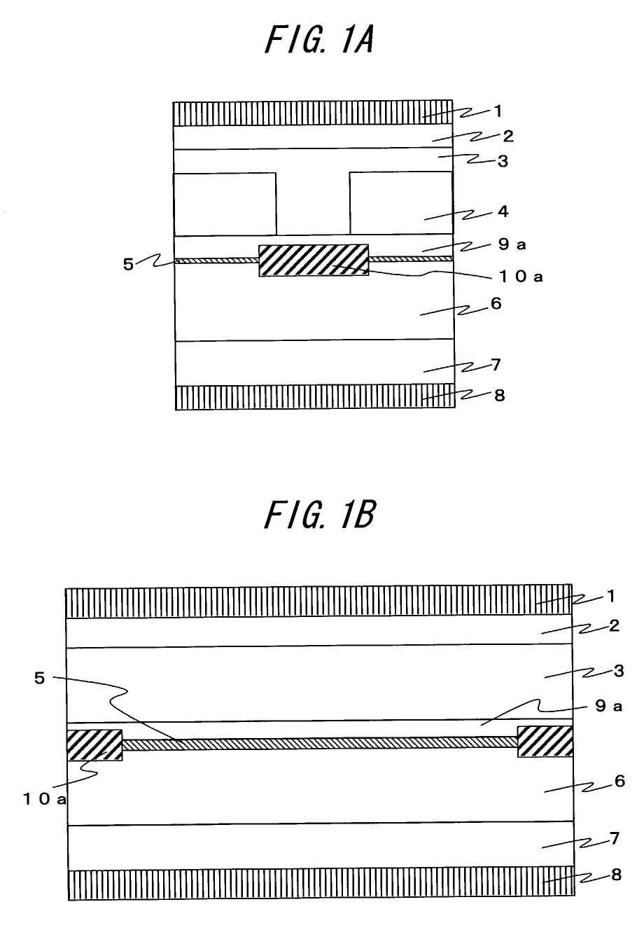

FIG. 1A is an end view of a window structure AlGaAs semiconductor laser device fabricated by controlling the dose and ion implantation energy at the time of Si ion implantation at 0.8×10¹⁴ atoms/cm² and 95 keV, respectively, so as to obtain a Si peak density in the semiconductor of 8.0×10¹⁸ atoms/cm³, and FIG. 1B is a central sectional view of the LD. As the conditions of a heat treatment after the ion implantation, 800° C. and 60 minutes were employed.

In FIG. 1A and FIG. 1B, reference numeral 1 denotes a surface electrode, 2 denotes a p-GaAs contact layer, 3 denotes a p-Al_{0.49}Ga_{0.51}As upper clad layer, 4 denotes an n-Al_{0.65}Ga_{0.35}As block layer, 5 denotes an Al_{0.33}Ga_{0.67}As/Al_{0.12}Ga_{0.88}As DQW (well layer=Al_{0.10}Ga_{0.90}As, 8.4 nm; barrier layer=Al_{0.35}Ga_{0.65}As, 8.4 nm) active layer, 6 denotes an n-Al_{0.48}Ga_{0.52}As lower clad layer, 7 denotes an n-GaAs substrate, 8 denotes a back side electrode, 9a denotes a p-Al_{0.48}Ga_{0.52}As upper clad layer (Zn doped), and 10a denotes a window structure region.

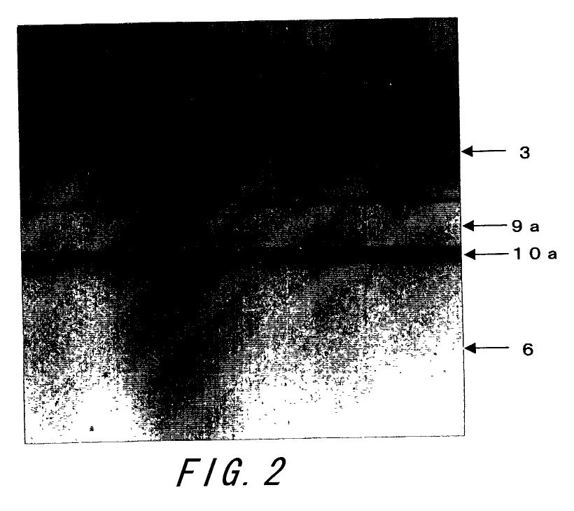

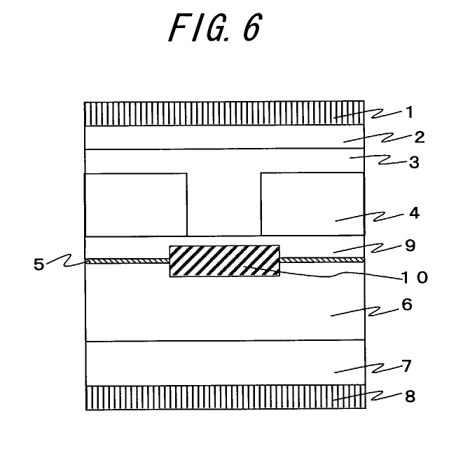

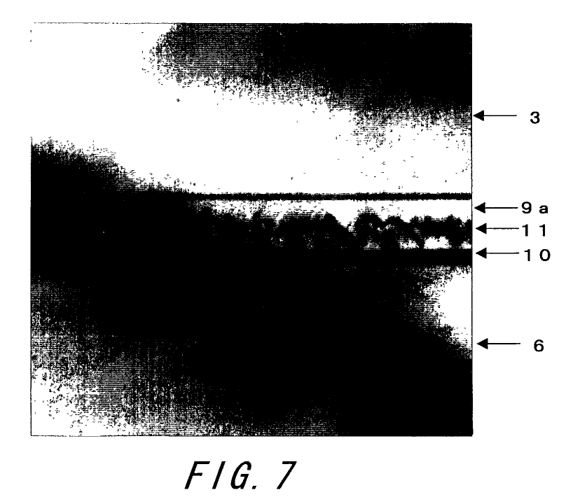

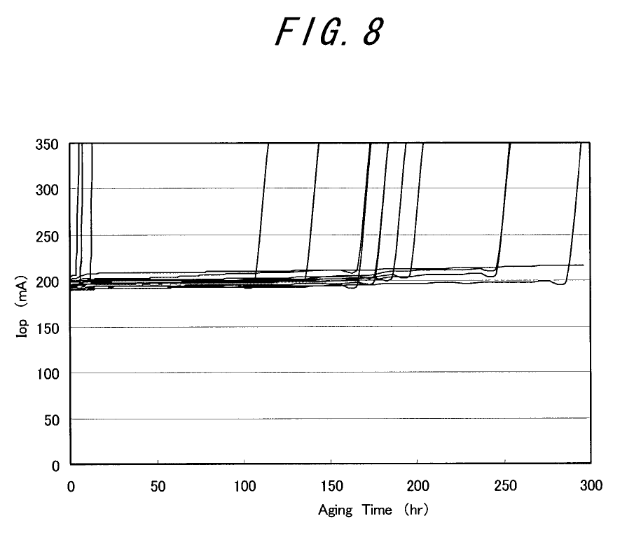

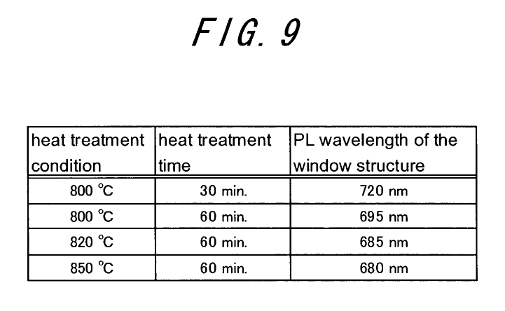

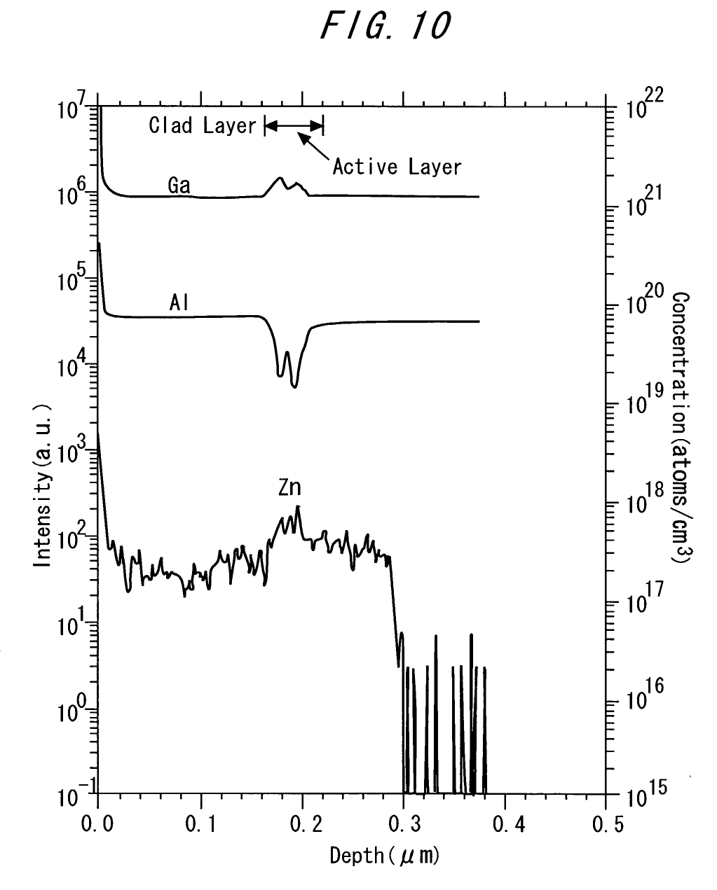

FIG. 2 shows a TEM photograph of a window region in the semiconductor laser device. The resolution of TEM was 1.7 angstrom. While in the case of a conventional semiconductor laser device having a Si peak density of 1.4×10¹⁹ atoms/cm³, dislocation loops 11 due to Si condensation were observed in an upper portion of the active layer, as shown in FIG. 6, no dislocation loops are observed in the semiconductor in and in the vicinity of the window structure region 10a in the semiconductor laser device having a silicon concentration peak value in and in the vicinity of the window structure region 10a of 8.0×10¹⁸ atoms/cm³ as in the present embodiment. The photoluminescence wavelength of the window structure in this embodiment is 700 nm, and a sufficient window effect is obtained.

The present inventors have empirically found that generation of dislocation loops is suppressed by setting the Si peak concentration at the time of implantation into the AlGaAs semiconductor to be not more than 1.0×10¹⁹ atoms/cm³. Namely, it has been found that in the case of an AlGaAs semiconductor laser device, it is possible to prevent the generation of dislocation loops by setting the Si peak density to be not more than 1.0×10¹⁹ atoms/cm³. However, as has been described above, it has been found by the present inventors' experiments that for disordering of the active layer 5 it is necessary to set the Si concentration in the active layer 5 to be generally not less than 1.0×10¹⁸ atoms/cm³. Accordingly, the Si peak concentration in the present semiconductor laser device must be in the range of 1.0×10¹⁸ to 1.0×10¹⁹ atoms/cm³.

Incidentally, in the cases of semiconductor laser devices based on other compounds, the Si peak density may be not more than the solid solubility limit in the compound semiconductor used for the semiconductor laser device.

In addition, since the dose and ion implantation energy at the time of Si ion implantation are respectively determined according to the structure of the semiconductor laser device and the kind of the compound semiconductor used, it goes without saying that the dose and ion implantation energy optimum for these conditions should be employed.

In the semiconductor laser device according to the present embodiment, dislocation loops which cause deterioration of reliability are reduced (to below the resolving power of the TEM), so that reliability can be improved.

Second Embodiment

In the case where Zn is used as an acceptor as in the conventional semiconductor laser device, there arises the problem that Zn diffuses during a heat treatment to make the temperature characteristics worse. In order to prevent the deterioration of the temperature characteristics due to thermal diffusion of Zn (diffusion of acceptor), it suffices to employ as the acceptor an impurity which is less susceptible to thermal diffusion than Zn.

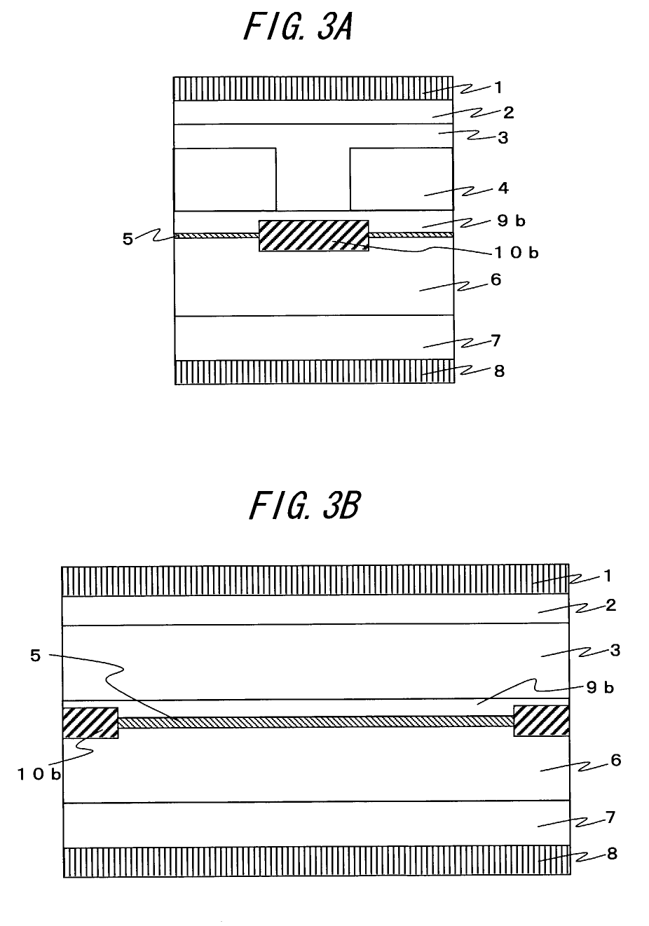

FIG. 3A is an end view of a semiconductor laser device in which carbon (C) is employed as an acceptor doped into the p-Al_{0.48}Ga_{0.52}As clad layer 9, in place of zinc (Zn) used in a first embodiment, and FIG. 3B is a central sectional view of the LD. As the conditions of a heat treatment after the ion implantation, 820° C. and 60 minutes were employed. The Si peak concentration in and in the vicinity of the window structure region 10a is in the range of 1.0×10¹⁸ to 1.0×10¹⁹ atoms/cm³.

In FIG. 3A and FIG. 3B, reference numeral 1 denotes a surface electrode, 2 denotes a p-GaAs contact layer, 3 denotes a p-Al_{0.49}Ga_{0.51}As upper clad layer, 4 denotes an n-Al_{0.65}Ga_{0.35}As block layer, 5 denotes an Al_{0.33}Ga_{0.67}As/Al_{0.12}Ga_{0.88}As DQW (well layer=Al_{0.10}Ga_{0.90}As, 0.84 nm; barrier layer=Al_{0.35}Ga_{0.65}As, 8.4 nm) active layer, 6 denotes an n-Al_{0.48}Ga_{0.52}As lower clad layer, 7 denotes an n-GaAs substrate, 8 denotes a back side electrode, 9b denotes a p-Al_{0.48}Ga_{0.52}As upper clad layer (C doped), and 10b denotes a window structure region.

Here, it is possible to dope (introduce) C in an amount of not less than 1.5×10¹⁸ atoms/cm³ by controlling the V/III ratio (to lower the flow rate ratio of a Group V material gas and a Group III material gas) and the growth temperature (to lower the growth temperature) at the time of growth of the p-Al_{0.48}Ga_{0.52}As upper clad layer 9b (MOCVD growth).

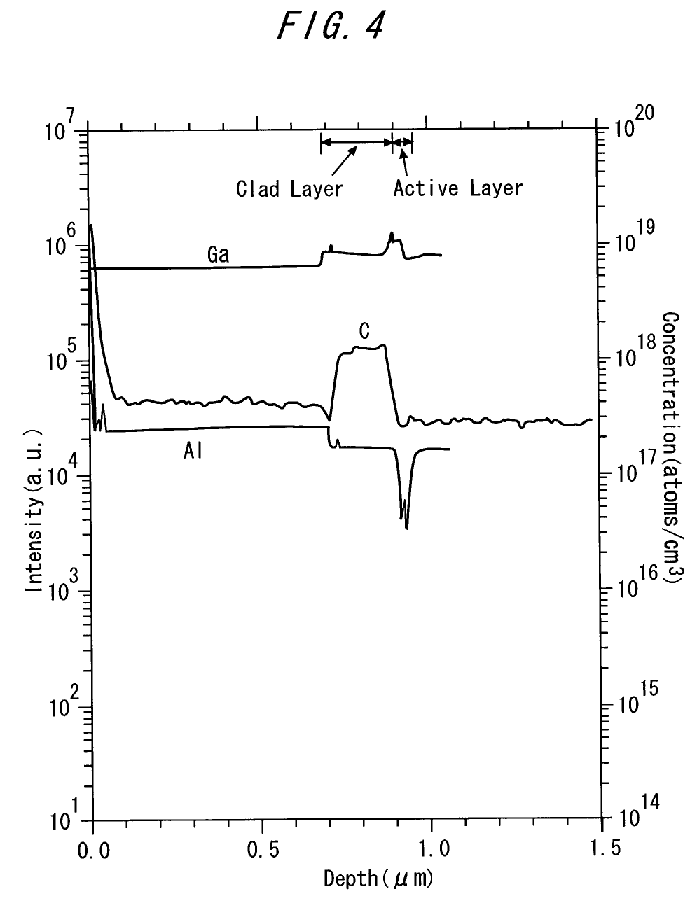

In the Group III-V compound semiconductor as in the present embodiment, the thermal diffusion coefficient of C is smaller than that of Zn generally used as the acceptor, and, therefore, it is expected that the diffusion of the acceptor during the heat treatment carried out after Si ion implantation is small. FIG. 4 shows the results of SIMS analysis for the case of a heat treatment at 820° C. for 60 minutes. It is seen that, in spite of the augmented heat treatment at 820° C. for 60 minutes, C has little diffused and the carrier concentration in the p-Al_{0.48}Ga_{0.52}As clad layer 9b is maintained at a desired value.

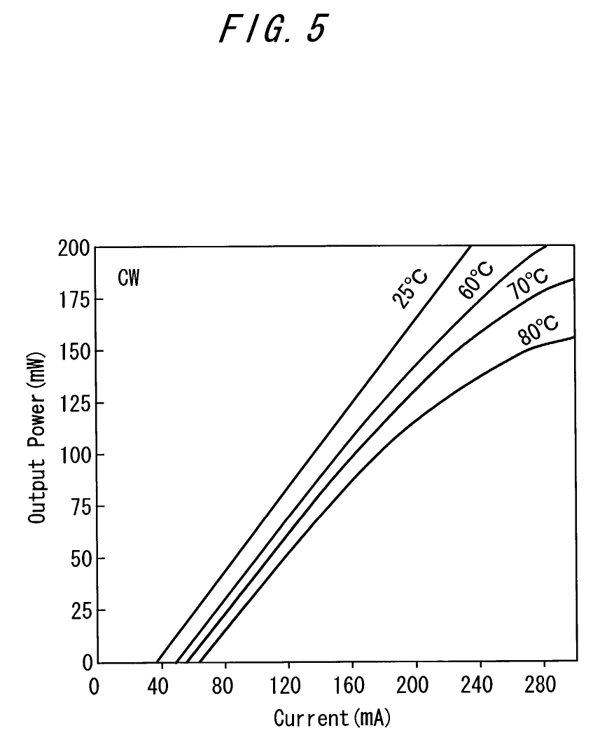

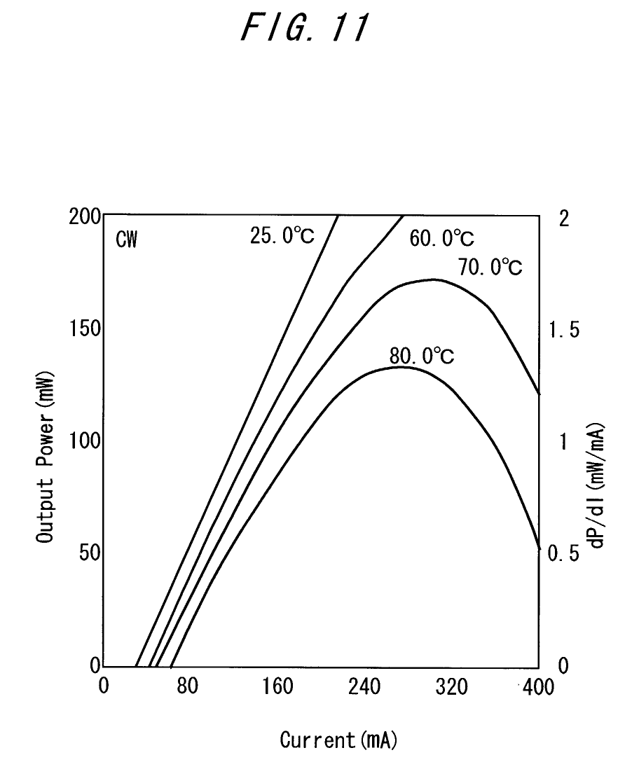

Temperature dependence of operating current-light output characteristics of a semiconductor laser device according to the present embodiment is shown in FIG. 5, from which it is seen that good characteristics with little deterioration can be obtained even at elevated temperature ranges, as contrasted to the case of the conventional semiconductor laser device shown in FIG. 11.

In the present embodiment, by use of C having a thermal diffusion coefficient smaller than that of Zn as a p-type dopant, the diffusion of the acceptor which would otherwise occur during the heat treatment in fabrication of the window structure region 10b is prevented, and it is possible to prevent the deterioration of temperature characteristics of the semiconductor laser device resulting from diffusion of the acceptor.

Third Embodiment

While carbon having a thermal diffusion coefficient smaller than that of Zn has been employed as a p-type dopant in a second embodiment, magnesium may also be employed in view of the same property.

A semiconductor laser device according to the present invention including a window structure region formed by disordering an active layer or active layers of a quantum well structure by silicon ion implantation and a subsequent heat treatment can prevent degradation of the semiconductor laser device arising from dislocation loops and improve reliability thereof since a dislocation loop is substantially absent in and in the vicinity of the window structure region.

In addition, since no dislocation loop is observed in and in the vicinity of the window structure region upon observation using a transmission electron microscope (resolution of 1.7 angstrom), degradation of the semiconductor laser device arising from dislocation loops can be prevented, and reliability of the semiconductor device can be improved.

Besides, carbon is employed as a p-type dopant introduced into a p-type clad layer adjacent to the active layer, whereby diffusion of the p-type dopant which might occur during the heat treatment for forming the window structure region is prevented, and it is possible to prevent the deterioration of temperature characteristics of the semiconductor laser device resulting from the diffusion of the p-type dopant.

Alternatively, magnesium is employed as a p-type dopant introduced into the p-type clad layer adjacent to the active layer, whereby diffusion of the p-type dopant which might occur during the heat treatment for forming the window structure region is prevented, and it is possible to prevent the deterioration of temperature characteristics of the semiconductor laser device resulting from the diffusion of the p-type dopant.

In addition, a semiconductor laser device according to the present invention including a window structure region formed by disordering an active layer or active layers of a quantum well structure by silicon ion implantation and a subsequent heat treatment can prevent generation of a dislocation loop in and in the vicinity of the window structure region and improve reliability thereof since the peak value of the concentration of silicon in and in the vicinity of the window structure region is in the range of 1.0×10¹⁸ to 1.0×10¹⁹ atoms/cm³.

Besides, carbon is employed as a p-type dopant introduced into a p-type clad layer adjacent to the active layer, whereby diffusion of the p-type dopant which might occur during the heat treatment for forming the window structure region is prevented, and it is possible to prevent the deterioration of temperature characteristics of the semiconductor laser device resulting from the diffusion of the p-type dopant.

Alternatively, magnesium is employed as a p-type dopant introduced into the p-type clad layer adjacent to the active layer, whereby diffusion of the p-type dopant which might occur during the heat treatment for forming the window structure region is prevented, and it is possible to prevent the deterioration of temperature characteristics of the semiconductor laser device resulting from the diffusion of the p-type dopant.

It is further understood that the foregoing description is a preferred embodiment of the disclosed apparatus and that various changes and modifications may be made in the invention without departing from the spirit and scope thereof.

The entire disclosure of a Japanese Patent Application No.2001-179755, filed on Jun. 14, 2001 including specification, claims drawings and summary, on which the Convention priority of the present application is based, are incorporated herein by reference in its entirety.

What is claimed is:

1. A semiconductor laser device comprising a window structure region formed by disordering an active layer or active layers of a quantum well structure by silicon ion implantation and a subsequent heat treatment, wherein
a dislocation loop is substantially absent in and in the vicinity of said window structure region.

2. The semiconductor laser device according to claim 1, wherein no dislocation loop is observed in and in the vicinity of said window structure region upon observation using a transmission electron microscope.

3. The semiconductor laser device according to claim 2, wherein the resolution of the transmission electron microscope is in excess of 1.7 angstrom.

4. The semiconductor laser device according to claim 1, wherein carbon is used as a p-type dopant introduced into a p-type clad layer adjacent to said active layer.

5. The semiconductor laser device according to claim 1, wherein magnesium is used as a p-type dopant introduced into a p-type clad layer adjacent to said active layer.

6. A semiconductor laser device comprising a window structure region formed by disordering an active layer or active layers of a quantum well structure by silicon ion implantation and a subsequent heat treatment, wherein
the peak value of concentration of silicon in and in the vicinity of said window structure region is in the range of 1.0×10¹⁸ to 1.0×10¹⁹ atoms/cm³.

7. The semiconductor laser device according to claim 6, wherein carbon is used as a p-type dopant introduced into a p-type clad layer adjacent to said active layer.

8. The semiconductor laser device according to claim 6, wherein magnesium is used as a p-type dopant introduced into a p-type clad layer adjacent to said active layer.

9. A method of manufacturing a semiconductor laser device having a window structure region in an active layer comprising:
an ion implantation process that set the peak value of concentration of silicon in and in the vicinity of said window structure region to be the range of 1.0×10¹⁸ to 1.0×10¹⁹ atoms/cm³.
